(19) United States
(12) Patent Application Publication
(10) Pub. No.: US 2026/0026020 A1
(43) Pub. Date: Jan. 22, 2026

(54) SEMICONDUCTOR STRUCTURE AND MANUFACTURING METHOD THEREOF

(71) Applicant: UNITED MICROELECTRONICS CORP., Hsin-Chu City (TW)

(72) Inventors: Nan-Yuan Huang, Tainan City (TW); Chung-Yi Chiu, Tainan City (TW); Huang-Ren Wei, Tainan City (TW); Cheng-Ting Shih, Changhua County (TW)

(73) Assignee: UNITED MICROELECTRONICS CORP., Hsin-Chu City (TW)

(21) Appl. No.: 18/796,308

(22) Filed: Aug. 7, 2024

(30) Foreign Application Priority Data
Jul. 18, 2024 (CN) 202410964400.8

(51) Int. Cl. H01L 29/94; H01L 21/768; H01L 23/522; H01L 29/66

(52) U.S. Cl. CPC H10D 1/665; H01L 21/76816; H01L 21/76831; H01L 23/5226; H10D 1/047

(57) ABSTRACT

A manufacturing method of a semiconductor structure includes the following steps. A silicon substrate is provided, and a patterning process is performed to the silicon substrate for forming first trenches in the silicon substrate. A part of the silicon substrate is patterned to be a first fin-shaped structure located between two of the first trenches adjacent to each other in a horizontal direction by the patterning process, and a top corner of the first fin-shaped structure protrudes outwards in the horizontal direction. An oxidation process is performed to the first fin-shaped structure, and a part of the first fin-shaped structure is oxidized to be an oxide layer by the oxidation process. A removing process is performed for removing the oxide layer, and the top corner of the first fin-shaped structure becomes a curved sidewall via the oxidation process and the removing process.

### BACKGROUND OF THE INVENTION

### 1. Field of the Invention

The present invention relates to a semiconductor structure and a manufacturing method thereof, and more particularly, to a semiconductor structure including a trench and a manufacturing method thereof.

### 2. Description of the Prior Art

In modern society, the micro-processor systems composed of integrated circuits (ICs) are applied popularly in our living. Many electrical products, such as personal computers, mobile phones, and home appliances, include ICs. With the development of technology and the increasingly imaginative applications of electrical products, the design of ICs tends to be smaller, more delicate and more diversified.

In the recent electrical products, IC devices, such as metal oxide semiconductor (MOS) transistors, capacitors, or resistors, are produced from silicon based substrates that are fabricated by semiconductor manufacturing processes. A complicated IC system may be composed of the IC devices electrically connected with one another. Generally, a capacitor structure may be composed of a top electrode, a dielectric layer, and a bottom electrode. Additionally, to accommodate the exceedingly demanding power integrity (PI) requirements for the advanced artificial intelligence (AI) and high performance computing (HPC) components, high dielectric constant based deep trench capacitors (DTC) have been integrated in the silicon interposer including through silicon via (TSV) and interconnection structures for being applied in advanced packaging technology (such as CoWoS package technology). Capacitor structures generally require multiple layers of metal electrodes and high dielectric constant film layers, and related manufacturing yield will be affected when the stacking condition of the material layers in the capacitor structure is influenced by the shape of the trenches corresponding to the DTC.

### SUMMARY OF THE INVENTION

A semiconductor structure and a manufacturing method thereof are provided in the present invention. An oxidation process and a removing process are performed after trenches are formed in a silicon substrate for adjusting a shape of a fin-shaped structure located between the trenches adjacent to each other, and the manufacturing yield may be enhanced accordingly.

According to an embodiment of the present invention, a manufacturing method of a semiconductor structure is provided. The manufacturing method includes the following steps. A silicon substrate is provided, and a patterning process is performed to the silicon substrate for forming first trenches in the silicon substrate. A part of the silicon substrate is patterned to be a first fin-shaped structure located between two of the first trenches adjacent to each other in a horizontal direction by the patterning process, and a top corner of the first fin-shaped structure protrudes outwards in the horizontal direction. An oxidation process is performed to the first fin-shaped structure, and a part of the first fin-shaped structure is oxidized to be an oxide layer by the oxidation process. A removing process is performed for removing the oxide layer, and the top corner of the first fin-shaped structure becomes a curved sidewall via the oxidation process and the removing process.

According to an embodiment of the present invention, a semiconductor structure is provided. The semiconductor structure includes a silicon substrate and trenches. The trenches are disposed in the silicon substrate, and the silicon substrate includes a fin-shaped structure located between two of the trenches adjacent to each other in a horizontal direction. The fin-shaped structure includes a flat top surface, a curved sidewall, and a tilted sidewall. The curved sidewall is connected with the flat top surface, the curved sidewall is located between the flat top surface and a first horizontal plane in a vertical direction, and a width of the fin-shaped structure continuously increases from the flat top surface to the first horizontal plane. The tilted sidewall is located between a second horizontal plane and a third horizontal plane in the vertical direction, the second horizontal plane is located under the first horizontal plane in the vertical direction, the third horizontal plane is located under the second horizontal plane in the vertical direction, and the width of the fin-shaped structure continuously decreases from the second horizontal plane to the third horizontal plane.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic drawings illustrating a manufacturing method of a semiconductor structure according to an embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing illustrating an enlargement of a region in FIG. 5, FIG. 7 is a schematic drawing in a step subsequent to FIG. 5, and FIG. 8 is a schematic drawing in a step subsequent to FIG. 7.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

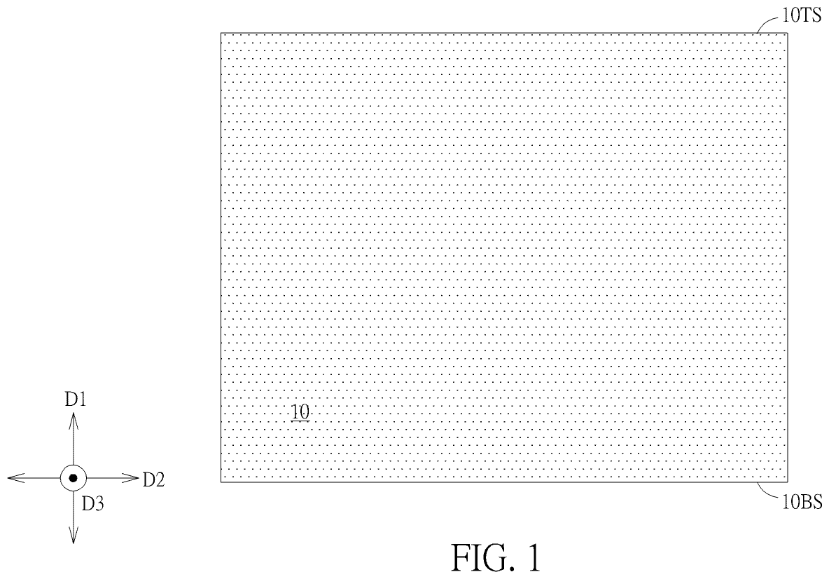

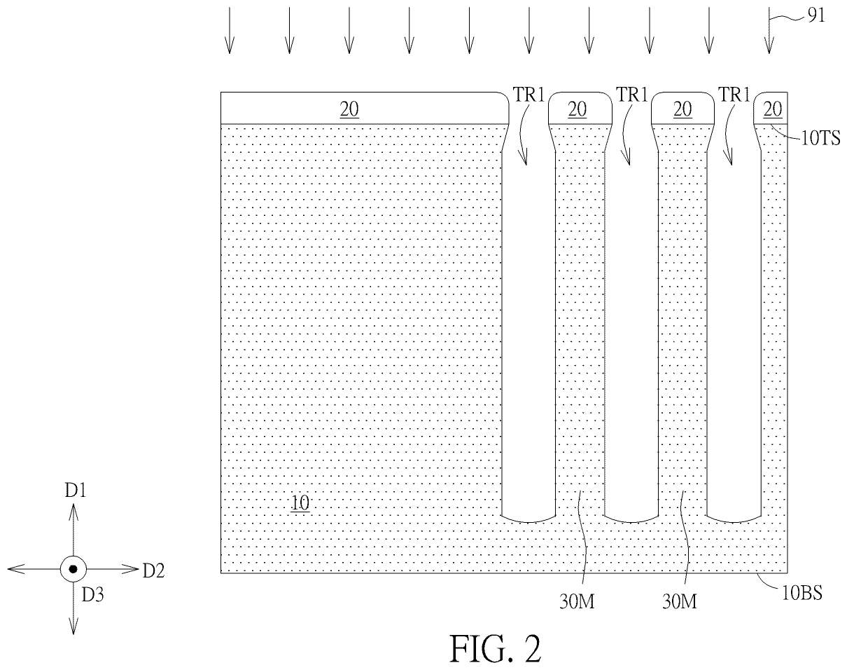

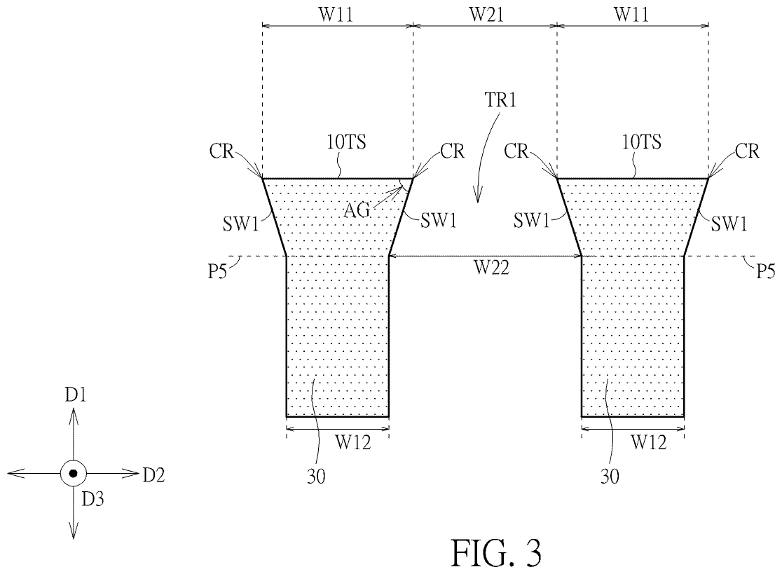

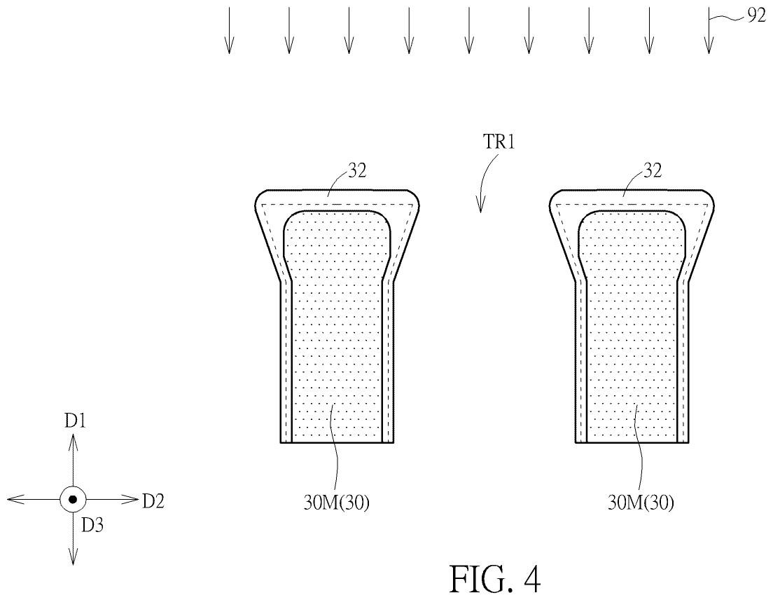

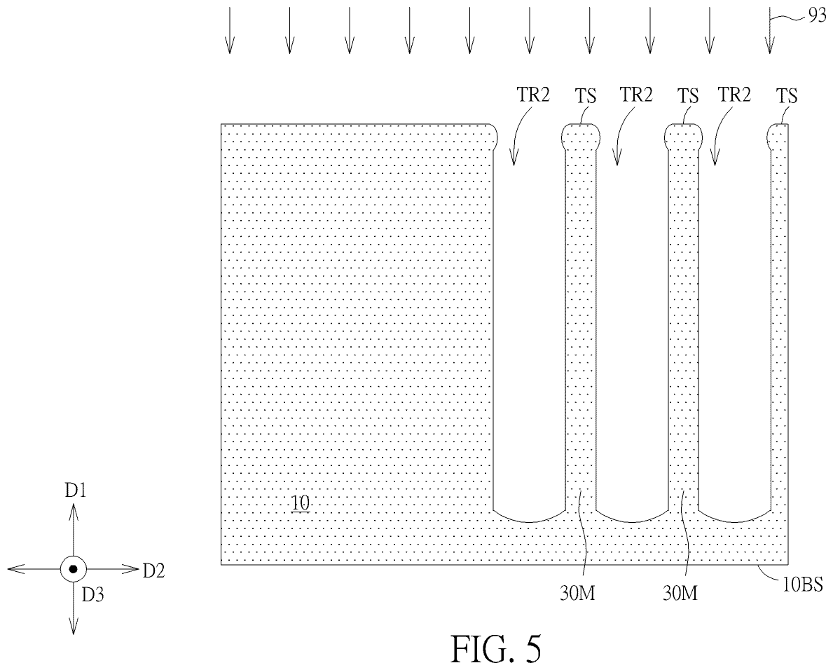

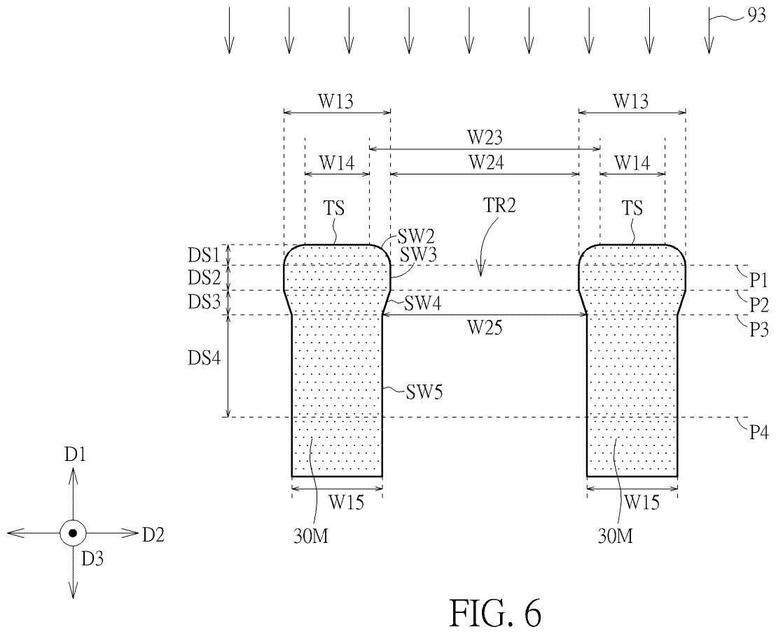

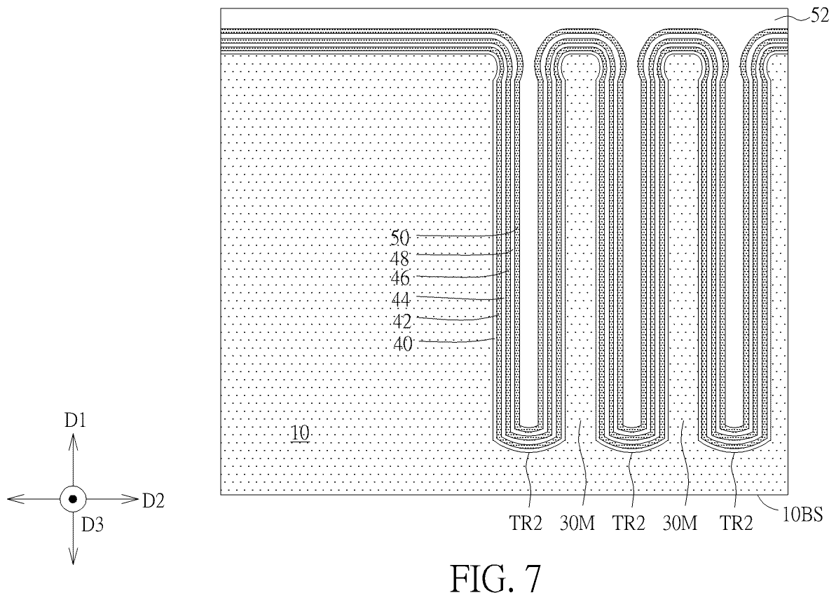

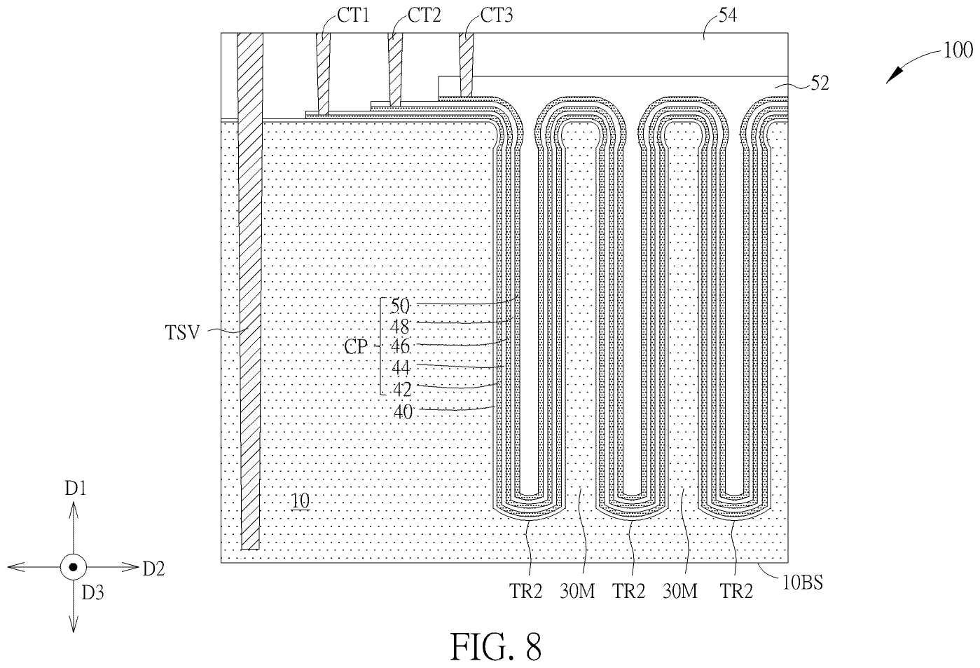

Please refer to FIGS. 1-8. FIGS. 1-8 are schematic drawings illustrating a manufacturing method of a semiconductor structure according to an embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, FIG. 5 is a schematic drawing in a step subsequent to FIG. 4, FIG. 6 is a schematic drawing illustrating an enlargement of a region in FIG. 5, FIG. 7 is a schematic drawing in a step subsequent to FIG. 5, and FIG. 8 is a schematic drawing in a step subsequent to FIG. 7. In addition, FIGS. 3, 4, and 6 may be respectively regarded as a schematic drawing illustrating a partial enlargement of a fin-shaped structure. A manufacturing method of a semiconductor structure is provided in this embodiment and includes the following steps. Firstly, as shown in FIG. 1, a silicon substrate 10 is provided. A vertical direction D1 may be regarded as a thickness direction of the silicon substrate 10, and the silicon substrate 10 may have a top surface 10TS and a bottom surface 10BS opposite to the top surface 10TS in the vertical direction D1. Subsequently, as shown in FIG. 2 and FIG. 3, a patterning process 91 is performed to the silicon substrate 10 for forming first trenches (such as trenches TR1) in the silicon substrate 10. A part of the silicon substrate 10 is patterned to be a first fin-shaped structure (such as a fin-shaped structure 30) located between two of the trenches TR1 adjacent to each other in a horizontal direction D2 by the patterning process 91, and a top corner CR of the fin-shaped structure 30 protrudes outwards in the horizontal direction D2. As shown in FIG. 4, an oxidation process 92 is then performed to the fin-shaped structure 30, and a part of the fin-shaped structure 30 is oxidized to be an oxide layer 32 by the oxidation process 92. As shown in FIGS. 3-6, a removing process 93 is performed for removing the oxide layer 32, and the top corner CR of the fin-shaped structure 30 becomes a curved sidewall SW2 via the oxidation process 92 and the removing process 93.

As shown in FIG. 2, the trench TR1 may extend from the top surface 10TS of the silicon substrate 10 towards the bottom surface 10BS of the silicon substrate 10 in the vertical direction D1 without completely penetrating through the silicon substrate 10. In some embodiments, the trenches TR1 may be separated from one another, each of the trenches TR1 may extend inn another horizontal direction (such as a horizontal direction D3), and the horizontal direction D3 may be orthogonal to the horizontal direction D2, but not limited thereto. In some embodiments, horizontal directions substantially orthogonal to the vertical direction D1 (such as the horizontal direction D2 and the horizontal direction D3) may be substantially parallel with the top surface 10TS and/or the bottom surface 10BS of the silicon substrate 10, but not limited thereto. In this description, a distance between the bottom surface 10BS of the silicon substrate 10 and a relatively higher location and/or a relatively higher part in the vertical direction D1 may be greater than a distance between the bottom surface 10BS of the silicon substrate 10 and a relatively lower location and/or a relatively lower part in the vertical direction D1. The bottom or a lower portion of each component may be closer to the bottom surface 10BS of the silicon substrate 10 in the vertical direction D1 than the top or upper portion of this component. Another component disposed above a specific component may be regarded as being relatively far from the bottom surface 10BS of the silicon substrate 10 in the vertical direction D1, and another component disposed under a specific component may be regarded as being relatively close to the bottom surface 10BS of the silicon substrate 10 in the vertical direction D1. Additionally, in this description, a top surface of a specific component may include the topmost surface of this component in the vertical direction D1, and a bottom surface of a specific component may include the bottommost surface of this component in the vertical direction D1, but not limited thereto. In this description, the condition that a certain component is disposed between two other components in a specific direction may include but is not limited to a condition that the certain component is sandwiched between the two other components in the specific direction.

Specifically, the manufacturing method in this embodiment may include but is not limited to the following steps and/or the following features. As shown in FIG. 2, in some embodiments, a patterned mask layer 20 may be formed on the top surface 10TS of the silicon substrate 10, and an etching step using the patterned mask layer 20 as a mask may be performed to the silicon substrate 10 for forming the trenches TR1. In other words, the patterning process 91 may include the step of forming the patterned mask layer 20 and the etching step described above, but not limited thereto. Additionally, in some embodiments, the material of the patterned mask layer 20 may include oxide, and the patterned mask layer 20 may be formed by forming an oxide layer on the silicon substrate 10 and patterning this oxide layer. In some embodiments, a method of patterning the oxide layer may include a dry etching step or other suitable patterning approaches, and the reaction gas used in the dry etching step may include sulfur hexafluoride (SF₆), octafluorocyclobutane (C₄F₈), or other suitable reactants. It is worth noting that, in some embodiments, polymer byproducts tend to be formed and remain on the edge of the patterned mask layer 20 when the dry etching step is performed to the oxide layer for forming the patterned mask layer 20, and the top corner of the fin-shaped structure described above may be formed because the etching condition of the silicon substrate 10 is influenced by the polymer byproducts in the step of etching the silicon substrate 10, but not limited thereto.

As shown in FIG. 2 and FIG. 3, the patterned mask layer 20 may be removed after the trenches TR1 are formed. In some embodiments, the patterned mask layer 20 may be removed by a dilute hydrofluoric acid (dHF) cleaning process or other suitable approaches. Additionally, as shown in FIG. 2 and FIG. 3, in some embodiments, the silicon substrate 10 may include a plurality of the fin-shaped structures 30, and the fin-shaped structures 30 and the trenches TR1 may be alternately arranged in the horizontal direction D2. Each of the fin-shaped structures 30 may extend in the horizontal direction D3 substantially, the top corner CR of each of the fin-shaped structures 30 may protrude outwards in the horizontal direction D2, and the upper part of each of the fin-shaped structures 30 may have a portion similar to a part of an inverted triangle in the cross-sectional diagram of the fin-shaped structure 30, but not limited thereto. In some embodiments, the top corner CR may include a part of a top surface of the fin-shaped structure 30 (for example, the top surface 10TS of the silicon substrate 10 may be regarded as the top surface of the fin-shaped structure 30, but not limited thereto) and a part of a tilted sidewall SW1 of the fin-shaped structure 30, the top surface 10TS is connected with the tilted sidewall SW1, and an included angle between the top surface 10TS and the tilted sidewall SW1 (such as an included angle AG facing the fin-shaped structure 30) may be less than 90 degrees. Each of the fin-shaped structures 30 may include the top surface 10TS which is substantially flat and the tilted sidewall SW1, a part of the top surface 10TS and a part of the tilted sidewall SW1 may constitute the top corner CR protruding outwards, and the tilted sidewall SW1 may be regarded as a sidewall gradually shrinking from the top surface 10TS to a lower position.

In some embodiments, the tilted sidewall SW1 may be located between the top surface 10TS and a fifth horizontal plane (such as a horizontal plane P5) in the vertical direction D1, and a width of the fin-shaped structure 30 may continuously decrease from the top surface 10TS to the horizontal plane P5. In this description, the width of the fin-shaped structure and the width of the trench may be regarded as the length of the fin-shaped structure in the horizontal direction D2 and the length of the trench in the horizontal direction D2, respectively. In this description, each horizontal plane may be a plane parallel with the horizontal direction D2 and the horizontal direction D3 and orthogonal to the vertical direction D1, and each horizontal plane intersects with a specific part of the fin-shaped structure. In some embodiments, the fin-shaped structure 30 may include a portion having a width W11 and a portion having a width W12, the portion having the width W11 may be aligned with (or flush with) and/or overlap the top surface 10TS substantially, and the portion having the width W12 may be aligned with (or flush with) and/or overlap the horizontal plane P5 substantially. Therefore, the width W11 may be regarded as being aligned with (or flush with) and/or overlapping the top surface 10TS substantially, and the width W12 may be regarded as being aligned with (or flush with) and/or overlapping the horizontal plane P5 substantially, but not limited thereto. The width W11 may be greater than the width W12, and the width of the fin-shaped structure 30 may continuously decrease from the top surface 10TS to the horizontal plane P5, such as gradually and continuously decreasing from the width W11 to the width W12. In some embodiments, the width of the portion of the fin-shaped structure 30 located under the horizontal plane P5 in the vertical direction D1 may be substantially constant (such as equal to the width W12 substantially), but not limited thereto. It is worth noting that, in this description, the condition that the width is substantially constant within a specific section may include but is not limited to a condition that this width is constant with a tolerance of ±5%. For example, the width of the portion of the fin-shaped structure 30 located under the horizontal plane P5 in the vertical direction D1 may range from 0.95 times the width W12 to 1.05 times the width W12, but not limited thereto. At least one of the trenches TR1 may be located between two of the fin-shaped structures 30 adjacent to each other in the horizontal direction D2, a width W21 of the topmost portion of the trench TR1 may be less than a width W22 of the trench TR1 located at the horizontal plane P5, and the width W21 may be substantially equal to the shortest distance between two of the fin-shaped structures 30 adjacent to each other in the horizontal direction D2.

In some embodiments, the depth uniformity of the trenches TR1 may be improved by the method of forming the trenches TR1 described above (such as but not limited to an improvement on the situation that the trenches TR1 with shallower depths are located at the relative edge area). However, the shape of the upper part of the fin-shaped structure 30 formed by this method is not conducive to the formation of the capacitor structure in the subsequent processes, and the shape of the upper part of the fin-shaped structure 30 has to be modified by other approaches. As shown in FIG. 4, a part of the fin-shaped structure 30 may be oxidized to be then oxide layer 32 by the oxidation process 92, and the area surrounded by the dotted line in FIG. 4 may be regarded as the shape of the fin-shaped structure 30 before the oxidation process 92. In some embodiments, the oxidation process 92 may include a thermal oxidation treatment or other suitable oxidation approaches. As shown in FIGS. 3-6, the removing process 93 may be performed after the oxidation process 92 for removing the oxide layer 32, and the top corner CR of the fin-shaped structure 30 may become the curved sidewall SW2 via the oxidation process 92 and the removing process 93. The removing process may include a dHF cleaning process or other suitable approaches for removing the oxide layer 32. In some embodiments, the top corner CR may be regarded as being etched to become the curved sidewall SW2 by the oxidation process 92 and the removing process 93, and the top corner CR may be rounded by the oxidation process 92 and the removing process 93 for reducing the negative influence of the shape of the upper portion of the fin-shaped structure on material layers subsequently formed (such as the stacked material layers in the capacitor structure). For instance, the top corner that are originally protruding outwards too seriously may cause problems such as cracks in the material layers formed on it and/or the width of the trench will be too small according and that is not conducive to the step of forming multiple material layers in the trench, but not limited thereto. Relatively, each of the trenches TR1 may be expanded to be a second trench (such as a trench TR2) by the oxidation process 92 and the removing process 93, each of the fin-shaped structures 30 may become a second fin-shaped structure (such as a fin-shaped structure 30M) including the curved sidewall SW2 via the oxidation process 92 and the removing process 93, and each of the fin-shaped structures 30M may be located between two of the trenches TR2 adjacent to each other in the horizontal direction D2.

In some embodiments, the curved sidewall SW2 may be located between a top surface TS of the fin-shaped structure 30M and a first horizontal plane (such as a horizontal plane P1) in the vertical direction D1, and a width of the fin-shaped structure 30M may continuously increase from the top surface TS to the horizontal plane P1. In some embodiments, the top surface TS may be a flat surface with a specific width (such as a width W14), but not limited thereto. In addition, the fin-shaped structure 30M may further include a tilted sidewall SW4, and the tilted sidewall SW4 may be located between a second horizontal plane (such as a horizontal plane P2) and a third horizontal plane (such as a horizontal plane P3) in the vertical direction D1. The horizontal plane P2 is located under the horizontal plane P1 in the vertical direction D1, the horizontal plane P3 is located under the horizontal plane P2 in the vertical direction D1, and the width of the fin-shaped structure 30M may continuously decrease from the horizontal plane P2 to the horizontal plane P3. In some embodiments, the fin-shaped structure 30M may further include a first vertical sidewall (such as a vertical sidewall SW3) and a second vertical sidewall (such as a vertical sidewall SW5) substantially parallel with the vertical direction D1 respectively, but not limited thereto. The vertical sidewall SW3 may be located between the horizontal plane P1 and the horizontal plane P2 in the vertical direction D1, the width of the fin-shaped structure 30M may be constant substantially from the horizontal plane P1 to the horizontal plane P2, and the vertical sidewall SW3 may be directly connected with the curved sidewall SW2 and the tilted sidewall SW4. The vertical sidewall SW5 may be located between the horizontal plane P3 and a fourth horizontal plane (such as a horizontal plane P4) in the vertical direction D1. The horizontal plane P4 is located under the horizontal plane P3 in the vertical direction D1, the width of the fin-shaped structure 30M may be substantially constant from the horizontal plane P3 to the horizontal plane P4, and a distance DS3 between the horizontal plane P2 and the horizontal plane P3 in the vertical direction D1 may be less than a distance DS4 between the horizontal plane P3 and the horizontal plane P4 in the vertical direction D1, but not limited thereto.

In some embodiments, the fin-shaped structure 30M may include a portion having a width W13, a portion having a width W14, and a portion having a width W15. The portion having the width W14 may be aligned with (or flush with) and/or overlap the top surface TS substantially, the portion having the width W13 may be aligned with (or flush with) and/or overlap the horizontal plane P1 and/or the horizontal plane P2 substantially, and the portion having the width W15 may be aligned with (or flush with) and/or overlap the horizontal plane P3 and/or the horizontal plane P4 substantially. Therefore, the width W14 may be regarded as being aligned with (or flush with) and/or overlapping the top surface TS substantially, the width W13 may be regarded as being aligned with (or flush with) and/or overlapping the horizontal plane P1 and/or the horizontal plane P2 substantially, and the portion having the width W15 may be regarded as being aligned with (or flush with) and/or overlapping the horizontal plane P3 and/or the horizontal plane P4 substantially, but not limited thereto. In some embodiments, the width W13 may be greater than the width W15 and the width W14, the width W15 may be greater than the width W14, and the width W14 may be greater than one-half the width W15, but not limited thereto. In some embodiments, the width of the fin-shaped structure 30M may continuously increase from the top surface TS to the horizontal plane P1 (such as increasing continuously from the width W14 to the width W13), the width of the portion of the fin-shaped structure 30M located between the horizontal plane P1 and the horizontal plane P2 in the vertical direction D1 may be substantially constant (such as being equal to the width W13 substantially), the width of the fin-shaped structure 30M may continuously decrease from the horizontal plan P2 to the horizontal plane P3 (such as decreasing gradually and continuously from the width W13 to the width W15), and the width of the portion the fin-shaped structure 30M located between the horizontal plane P3 and the horizontal plane P4 in the vertical direction D1 may be substantially constant (such as being equal to the width W15 substantially), but not limited thereto. In addition, the top corner of the fin-shaped structure may be rounded by the method described above, and the performance of making the top corner rounded may be ensured by controlling the process condition of the oxidation process described above. For example, the distance between the top surface TS and the horizontal plane P2 in the vertical direction D1 (such as a sum of a distance DS1 and a distance DS2) may be greater than the distance DS3 between the horizontal plane P2 and the horizontal plane P3 in the vertical direction D1 for ensuring the performance of making the top corner rounded, but not limited thereto.

As shown in FIG. 5 and FIG. 6, at least one of the trenches TR2 may be located between two of the fin-shaped structures 30M adjacent to each other in the horizontal direction D2. A width W23 of the topmost portion of the trench TR2 may be greater than a width W24 and a width W25 of the trench TR2, respectively. The width W24 may be regarded as a width of the portion of the trench TR2 located at the horizontal plane P1 and/or the horizontal plane P2, and the width W25 may be regarded as a width of the portion of the trench TR2 located at the horizontal plane P3 and/or the horizontal plane P4. The width W23 may be substantially equal to the maximum distance between two of the fin-shaped structures 30M adjacent to each other in the horizontal direction D2, and the width W24 may be substantially equal to the shortest distance between two of the fin-shaped structures 30M adjacent to each other in the horizontal direction D2, but not limited thereto. In addition, the depth of each of the trenches TR2 may be regarded as the distance between the top surface TS and the bottommost part of each of the trenches TR2 in the vertical direction D1, and an aspect ratio of the depth of each of the trenches TR2 to the width of each of the trenches TR2 (such as the width W23, the width W24, or the width W25 described above) may range from 27:1 to 37:1, but not limited thereto.

Subsequently, as shown in FIGS. 5-8, a capacitor structure CP may be formed after the removing process 93, and at least a part of the capacitor structure CP is formed in the trenches TR2. A method of forming the capacitor structure CP may include but is not limited to the following steps. As shown in FIG. 7, a liner layer 40, an electrically conductive layer 42, a capacitor dielectric layer 44, an electrically conductive layer 46, a capacitor dielectric layer 48, an electrically conductive layer 50, and a filling dielectric layer 52 may be formed sequentially. The liner layer 40 may be formed conformally on the silicon substrate 10 and the inner surfaces of the trenches TR2, the electrically conductive layer 42 may be formed conformally on the liner layer 40, the capacitor dielectric layer 44 may be formed conformally on the electrically conductive layer 42, the electrically conductive layer 46 may be formed conformally on the capacitor dielectric layer 44, the capacitor dielectric layer 48 may be formed conformally on the electrically conductive layer 46, the electrically conductive layer 50 may be formed conformally on the capacitor dielectric layer 48, the filling dielectric layer 52 may be formed on the electrically conductive layer 50, and the remaining space in the trenches TR2 may be substantially filled with the filling dielectric layer 52. Subsequently, as shown in FIG. 8, a patterning process may be performed to the liner layer 40, the electrically conductive layer 42, the capacitor dielectric layer 44, the electrically conductive layer 46, the capacitor dielectric layer 48, the electrically conductive layer 50, and the filling dielectric layer 52. After the patterning process, the electrically conductive layer 42 may include a portion located outside the trenches TR2 without overlapping the electrically conductive layer 46 and/or the electrically conductive layer 50 in the vertical direction D1, and the electrically conductive layer 46 may include a portion located outside the trenches TR2 without overlapping the electrically conductive layer 50 in the vertical direction D1. The electrically conductive layer 42, the capacitor dielectric layer 44, the electrically conductive layer 46, the capacitor dielectric layer 48, and the electrically conductive layer 50 that are patterned by the patterning process may constitute a capacitor structure CP.

The capacitor structure CP may be partly disposed in the trenches TR2 and partly disposed outside the trenches TR2, and the capacitor structure CP may be regarded as a deep trench capacitor (DTC), but not limited thereto. In addition, a dielectric layer 54, a contact structure CT1, a contact structure CT2, a contact structure CT3, and a through silicon via structure TSV may be formed after the capacitor structure CP is formed for forming a semiconductor structure 100 illustrated in FIG. 8. The contact structure CT1 may vertically penetrate through the dielectric layer 54 and the capacitor dielectric layer 44 located above the electrically conductive layer 42 for being electrically connected with the electrically conductive layer 42; the contact structure CT2 may vertically penetrate through the dielectric layer 54 and the capacitor dielectric layer 48 located above the electrically conductive layer 46 for being electrically connected with the electrically conductive layer 46; the contact structure CT3 may vertically penetrate through the dielectric layer 54 and the filling dielectric layer 52 located above the electrically conductive layer 50 for being electrically connected with the electrically conductive layer 50; and the through silicon via structure TSV may vertically penetrate through the dielectric layer 54, the liner layer 40, and at least a portion of the silicon substrate 10, but not limited thereto.

In some embodiments, the silicon substrate 10 may include a silicon semiconductor substrate, such as at least a portion of a silicon interposer for packaging processes, but not limited thereto. In addition, the liner layer 40 may include an oxide insulation material (such as silicon oxide) or other suitable insulation materials. The electrically conductive layer 42, the electrically conductive layer 46, and the electrically conductive layer 50 may respectively include a single layer or multiple layers of electrically conductive metal materials, such as titanium, tantalum, titanium nitride, tantalum nitride, or other suitable electrically conductive metal materials. The capacitor dielectric layer 44 and the capacitor dielectric layer 48 may respectively include a single layer or multiple layers of dielectric materials, such as silicon nitride, silicon-rich silicon nitride, silicon oxide, silicon oxynitride, a high dielectric constant (high-k) dielectric material (such as zirconium oxide, hafnium oxide, tantalum oxide, titanium oxide, or aluminum oxide), or other suitable dielectric materials. The filling dielectric layer 52 may include an oxide dielectric material (such as silicon oxide) or other suitable dielectric materials with better gap-filling performance. The dielectric layer 54 may include silicon oxide, fluorosilicate glass (FSG), a low dielectric constant (low-k) dielectric material, or other suitable dielectric materials. The contact structure CT1, the contact structure CT2, the contact structure CT3, and the through silicon via structure TSV may respectively include a barrier layer and an electrically conductive material disposed on this barrier layer, the barrier layer may include titanium nitride, tantalum nitride, or other suitable electrically conductive barrier materials, and the electrically conductive material may include a material with relatively low electrical resistivity, such as copper, aluminum, tungsten, and so forth.

As shown in FIG. 8 and FIG. 6, the semiconductor structure 100 in this embodiment include the silicon substrate 10 and the trenches TR2. The trenches TR2 are disposed in the silicon substrate 10, and the silicon substrate 10 includes a fin-shaped structure located between two of the trenches TR2 adjacent to each other in the horizontal direction D2 (such as the fin-shaped structure 30M). The fin-shaped structure 30M includes a flat top surface (such as the top surface TS), the curved sidewall SW2, and the tilted sidewall SW4. The curved sidewall SW2 is connected with the top surface TS, the curved sidewall SW2 is located between the top surface TS and the horizontal plane P1 in the vertical direction D1, and the width of the fin-shaped structure 30M continuously increases from the top surface TS to the horizontal plane P1. The tilted sidewall SW4 is located between the horizontal plane P2 and the horizontal plane P3 in the vertical direction D1, the horizontal plane P2 is located under the horizontal plane P1 in the vertical direction D1, the horizontal plane P3 is located under the horizontal plane P2 in the vertical direction D1, and the width of the fin-shaped structure 30M continuously decreases from the horizontal plane P2 to the horizontal plane P3.

In some embodiments, the silicon substrate 10 may include a plurality of the fin-shaped structures 30M, the fin-shaped structures 30M and the trenches TR2 may be arranged alternately in the horizontal direction D2, and each of the fin-shaped structures 30M may further include the vertical sidewall SW3 and the vertical sidewall SW5 described above, but not limited thereto. In addition, the semiconductor structure 100 may further include the liner layer 40, the capacitor structure CP, the filling dielectric layer 52, the dielectric layer 54, the contact structure CT1, the contact structure CT2, the contact structure CT3, and the through silicon via structure TSV described above. The liner layer 40 may be conformally disposed on the silicon substrate 10 and the inner surfaces of the trenches TR2, at least a part of the capacitor structure CP may be disposed in the trenches TR2, and the liner layer 40 may be located between the capacitor structure CP and the silicon substrate 10.

To summarize the above descriptions, according to the semiconductor structure and the manufacturing method thereof in the present invention, the oxidation process and the removing process may be carried out after the trenches are formed in the silicon substrate for adjusting the shape of the upper portion of the fin-shaped structure located between the trenches adjacent to each other. The negative influence of the shape of the fin-shaped structure on the material layers subsequently formed (such as the stacked material layers in the capacitor structure) may be reduced, and the related manufacturing yield may be enhanced accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor structure, comprising:
providing a silicon substrate;
performing a patterning process to the silicon substrate for forming first trenches in the silicon substrate, wherein a part of the silicon substrate is patterned to be a first fin-shaped structure located between two of the first trenches adjacent to each other in a horizontal direction by the patterning process, and a top corner of the first fin-shaped structure protrudes outwards in the horizontal direction;
performing an oxidation process to the first fin-shaped structure, wherein a part of the first fin-shaped structure is oxidized to be an oxide layer by the oxidation process; and
performing a removing process for removing the oxide layer, wherein the top corner of the first fin-shaped structure becomes a curved sidewall via the oxidation process and the removing process.

2. The manufacturing method of the semiconductor structure according to claim 1, wherein each of the first trenches is expanded to be a second trench by the oxidation process and the removing process.

3. The manufacturing method of the semiconductor structure according to claim 2, further comprising:
forming a capacitor structure after the removing process, wherein at least a part of the capacitor structure is formed in the second trenches.

4. The manufacturing method of the semiconductor structure according to claim 2, wherein the first fin-shaped structure becomes a second fin-shaped structure comprising the curved sidewall via the oxidation process and the removing process, and the second fin-shaped structure is located between two of the second trenches adjacent to each other in the horizontal direction.

5. The manufacturing method of the semiconductor structure according to claim 4, wherein the curved sidewall is located between a first top surface of the second fin-shaped structure and a first horizontal plane in a vertical direction, and a width of the second fin-shaped structure continuously increases from the first top surface to the first horizontal plane.

6. The manufacturing method of the semiconductor structure according to claim 5, wherein the second fin-shaped structure further comprises:
a first tilted sidewall located between a second horizontal plane and a third horizontal plane in the vertical direction, wherein the second horizontal plane is located under the first horizontal plane in the vertical direction, the third horizontal plane is located under the second horizontal plane in the vertical direction, and the width of the second fin-shaped structure continuously decreases from the second horizontal plane to the third horizontal plane.

7. The manufacturing method of the semiconductor structure according to claim 6, wherein the second fin-shaped structure further comprises:
a vertical sidewall located between the third horizontal plane and a fourth horizontal plane in the vertical direction, wherein the fourth horizontal plane is located under the third horizontal plane in the vertical direction, the width of the second fin-shaped structure is constant from the third horizontal plane to the fourth horizontal plane, and a distance between the second horizontal plane and the third horizontal plane in the vertical direction is less than a distance between the third horizontal plane and the fourth horizontal plane in the vertical direction.

8. The manufacturing method of the semiconductor structure according to claim 5, wherein the first top surface is a flat surface.

9. The manufacturing method of the semiconductor structure according to claim 1, wherein the top corner comprises a part of a second top surface of the first fin-shaped structure and a part of a second tilted sidewall of the first fin-shaped structure, the second top surface is connected with the second tilted sidewall, and an included angle between the second top surface and the second tilted sidewall is less than 90 degrees.

10. The manufacturing method of the semiconductor structure according to claim 9, wherein the second tilted sidewall is located between the second top surface and a fifth horizontal plane in a vertical direction, and a width of the first fin-shaped structure continuously decreases from the second top surface to the fifth horizontal plane.

11. A semiconductor structure, comprising:
a silicon substrate; and
trenches disposed in the silicon substrate, wherein the silicon substrate comprises a fin-shaped structure located between two of the trenches adjacent to each other in a horizontal direction, and the fin-shaped structure comprises:
a flat top surface;
a curved sidewall connected with the flat top surface, wherein the curved sidewall is located between the flat top surface and a first horizontal plane in a vertical direction, and a width of the fin-shaped structure continuously increases from the flat top surface to the first horizontal plane; and
a tilted sidewall located between a second horizontal plane and a third horizontal plane in the vertical direction, wherein the second horizontal plane is located under the first horizontal plane in the vertical direction, the third horizontal plane is located under the second horizontal plane in the vertical direction, and the width of the fin-shaped structure continuously decreases from the second horizontal plane to the third horizontal plane.

12. The semiconductor structure according to claim 11, wherein the fin-shaped structure further comprises:
a first vertical sidewall located between the first horizontal plane and the second horizontal plane in the vertical direction, wherein the width of the fin-shaped structure is constant from the first horizontal plane to the second horizontal plane, and the first vertical sidewall is directly connected with the curved sidewall and the tilted sidewall.

13. The semiconductor structure according to claim 11, wherein the fin-shaped structure further comprises:
a second vertical sidewall located between the third horizontal plane and a fourth horizontal plane in the vertical direction, wherein the fourth horizontal plane is located under the third horizontal plane, the width of the second fin-shaped structure is constant from the third horizontal plane to the fourth horizontal plane, and a distance between the second horizontal plane and the third horizontal plane in the vertical direction is less than a distance between the third horizontal plane and the fourth horizontal plane in the vertical direction.

14. The semiconductor structure according to claim 11, wherein a distance between the flat top surface and the second horizontal plane in the vertical direction is greater than a distance between the second horizontal plane and the third horizontal plane in the vertical direction.

15. The semiconductor structure according to claim 11, wherein a first width of the fin-shaped structure is aligned with the flat top surface, a second width of the fin-shaped structure is aligned with the second horizontal plane, and the first width is less than the second width.

16. The semiconductor structure according to claim 15, wherein a third width of the fin-shaped structure is aligned with the third horizontal plane, and the first width is less than the third width.

17. The semiconductor structure according to claim 11, further comprising:
a capacitor structure, wherein at least a part of the capacitor structure is disposed in the trenches.

18. The semiconductor structure according to claim 17, further comprising:
a liner layer conformally disposed on the silicon substrate and inner surfaces of the trenches, wherein the liner layer is located between the capacitor structure and the silicon substrate.

19. The semiconductor structure according to claim 18, further comprising:
a through silicon via structure penetrating through the liner layer and at least part of the silicon substrate vertically.

20. The semiconductor structure according to claim 11, wherein an aspect ratio of a depth of each of the trenches to a width of each of the trenches ranges from 27:1 to 37:1.
